(19) United States
(12) Patent Application Publication
(10) Pub. No.: US 2016/0227676 A1
(43) Pub. Date: Aug. 4, 2016

(54) CONTROLLING USAGE OF RESOURCES BASED ON OPERATING STATUS AND COMMUNICATIONS

(71) Applicant: HEWLETT PACKARD ENTERPRISE DEVELPMENT LP, Houston, TX (US)

(72) Inventors: Rongliang Zhou, Palo Alto, CA (US); Alan A. McReynolds, Palo Alto, CA (US); Thomas W. Christian, Fort Collins, CO (US); Cullen E. Bash, Palo Alto, CA (US)

(73) Assignee: HEWLETT PACKARD ENTERPRISE DEVELPMENT LP, Houston, TX (US)

(21) Appl. No.: 15/021,484

(22) PCT Filed: Sep. 26, 2013
(86) PCT No.: PCT/US2013/061902

§ 371 Date: Mar. 11, 2016

(51) Int. Cl. H05K 7/20

(52) U.S. Cl. CPC H05K 7/20836; F24F 2011/0002

(57) ABSTRACT

A first system is associated with an operating status. A second system is to affect the operating status based on usage of a shared resource. A restrictor is to control usage of the shared resource. A controller is to adjust the restrictor to control usage of the shared resource based on the operating status and a received communication indicating a resource status.

### BACKGROUND

Data centers, such as brick-and-mortar and containerized data centers, may use air-side economization. This technique may be based on using an air mover to direct cool outside air into the data center and remove a corresponding amount of hot air to outside of the data center. Multiple air handling units may utilize the cool outside air and redistribute it to the equipment in the data center. Each air handling unit may operate according to its own local behavior, to maximize its own benefit. However, the source of air as a cooling resource may be limited, and one air handling unit of the data center that maximizes its local benefit may deprive other air handling units in the data center.

### BRIEF DESCRIPTION OF THE DRAWINGS/FIGURES

FIG. 1 is a block diagram of an apparatus including a controller associated with communication according to an example.

FIG. 2 is a block diagram of a plurality of units in communication with each other according to an example.

FIG. 3 is a block diagram of a plurality of units in communication with a manager according to an example.

FIG. 4 is a flow chart based on adjusting a restrictor to control usage of a resource according to an example.

FIG. 5 is a flow chart based on an adjustment procedure according to an example.

FIG. 6 is a flow chart based on first and second modes of operation according to an example.

FIG. 7 is a flow chart based on a second mode of operation according to an example.

### DETAILED DESCRIPTION

Examples provided herein enable optimizing the distribution of a shared resource, such as cooling air, from air-side economization among multiple units (e.g., air handling units such as cooling units and/or heating units). Thus, the total amount of resources used (e.g., from chillers, cooling towers, fans, blowers, and/or other sources) may be minimized, leading to energy savings. Furthermore, the distribution of resources from air-side economization may be optimized to balance the loads of multiple air handling units to better distribute resources, which can be useful when handling a shortage of cooling capacity when serving high density computing areas, when particular units malfunction, or other situations affecting an air handling unit or delivery of resources.

The distribution of a resource from air-side economization may be optimized among multiple air handling units, to avoid air handling unit over-provisioning of outside air and cooling capacity shortages. In addition, the total amount of outside air needed for data center cooling is optimized, resulting in direct energy savings. Examples provided herein may be useful when an air handling unit, e.g., one serving a high density computing area, is short of cooling capacity, or a data center suffers a failure of other cooling systems used by air handling units (chilled water, mechanical refrigeration, and others, for example). Under such conditions, outside air economization may be the sole means of cooling for such a data center. By proportioning and diverting the outside air to where it will do the most good for a data center, examples may reduce overall costs and improve protection. Individual units may collaborate with each other to maximize benefits for the whole data center. In addition to cost savings, examples also provide benefits in terms of emergency situations. For example, when an air handling unit may be failing, another unit may reduce its usage of a shared resource (e.g., close its restrictor). Accordingly, the shared resource is conserved, enabling additional shared resources to be directed to those units most in need.

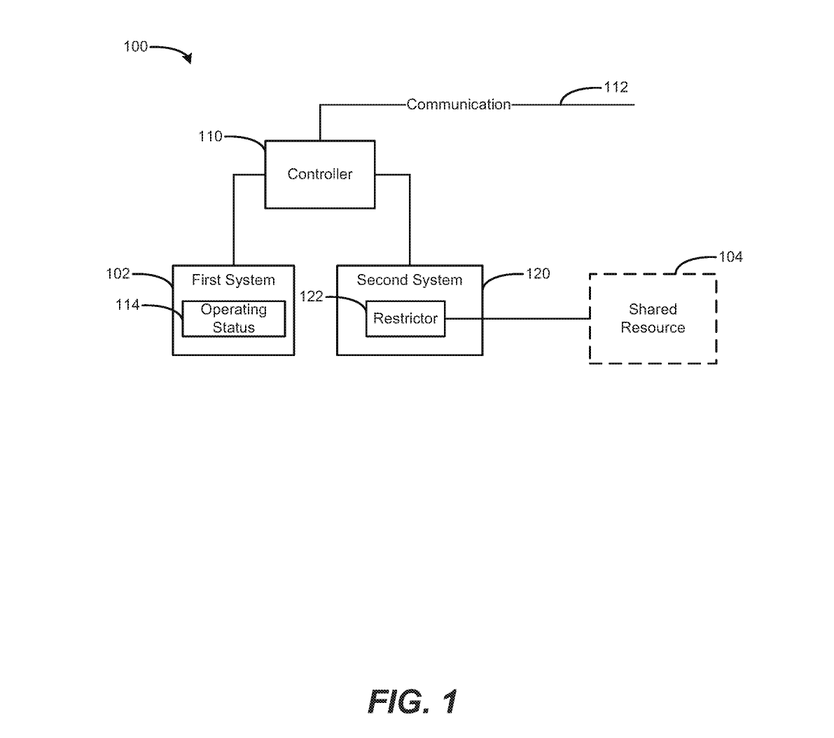

FIG. 1 is a block diagram of an apparatus 100 including a controller 110 associated with communication 112 according to an example. The controller 110 is coupled to first system 102 and second system 120. The first system 102 is associated with an operating status 114. The second system 120 includes a restrictor 122, associated with shared resource 104.

The apparatus 100 may interact with first/second systems 102, 120, such as cooling resources and cooling resource provisioning systems including air handling units. In an example, the first system 102 may be a computer room air conditioning (CRAC) unit. In an alternate example, the apparatus 100 may be an air handling unit based on the first system 102 and augmented by the addition of the second system 120 and controller 110. A cooling resource/system may include associated support material such as pumps, piping, ducts, vents, airflow pathways, etc. Although not specifically shown in FIG. 1, the first system 102 may include its own controller, e.g., an embedded controller to collect, monitor, and otherwise interact with operating status 114 of the first system 102, and/or to communicate with controller 110. In an example, operating status 114 may include data corresponding to the first system 102. Furthermore, examples provided herein may include heating applications, and are not limited to cooling. Thus, all references to cooling may be interpreted to include heating.

First system 102, such as a CRAC unit, may be used in an example to provide cool supply air to racks of equipment through a shared under-floor plenum. Hot air may exit from a back of the racks, and enter a shared ceiling plenum and return to the CRAC units. A CRAC may circulate the air using fans in the CRAC unit, and air also may be circulated by fans in the objects to be cooled themselves (e.g., computer equipment). The first system 102 (e.g., CRAC unit) may give off its heat loads to a chiller plant (e.g., via a chilled water) that interfaces with a cooling tower. Performance of the first system 102 may be augmented based on, e.g., a shared air second system 120 using outside air as the shared resource 104. The system may use ducts in the ceiling to bring in cool outside air and reject hot exhaust air. Variable speed intake and exhaust blowers may be used to facilitate air exchange and balance room pressure.

The first system 102 is to interact with a first resource. The first system 102 may be an air handling unit, and also may be based on a shared resource (e.g., based on chilled coolant such as water for cooling a supply airflow), and may be based on a non-shared (individual) resource, e.g., a system based on a vapor compression cycle, a heatsink with a fan, etc. for cooling the supply airflow. Example systems are not limited to individual or shared resource types. Thus, the second system 120, associated with shared resource 104, is not limited to air, and also may include other shared resources such as chilled water or other coolant. Examples are not limited to cooling, and may include heating, maintaining a thermal status, or providing varying temperature conditioning.

The second system 120 is to include restrictor 122 to change the flow of shared resource 104 through the second system 120. The restrictor 122 may be controlled and/or monitored by the controller 110. The second system 120 (and/or controller 110) may be provided as an augmentation coupled to the first system 102, e.g., as a physical bolt-on that may be added to a stand-alone CRAC first system 102. The second system 120 may include ducting, restrictors, sensors, actuators, controllers, and other components for augmenting the functionality of the first system 102. For example, the second system 120 may include ducting to receive outside air, along with outer sensors and other supporting components at the outside air source to obtain information that may be exchanged with the controller 110 (and/or an embedded controller at the first system 102, not shown in FIG. 1). Second system 120, similar to first system 102, may include its own (e.g., embedded) controller.

The controller 110 may interact with operating status 114 based on various features/measurements, including collecting information from first system 102 regarding operating status 114, and providing information to first system 102 to affect operating status 114. For example, the operating status 114 can include various features such as whether a temperature is too low or too high, or whether a load is too low or too high, and an identifier for the corresponding apparatus/air handling unit. Controller 110 may control both the first system 102 and the second system 120, according to a single objective, enabling the first and second systems 102, 120 to perform as a system together to achieve a desired behavior under the control of controller 110. Controller 110 may provide functionality that may not be available at a standalone CRAC unit (i.e., first system 102) having an embedded controller to serve only its own ends. Accordingly, the controller 110 may maintain a desired thermal environment based on one or more air handling units including first system 102 (or other air handlers not specifically shown in FIG. 1), including the ability to optimize thermal performance within given energy and/or cost constraints, even for multiple units across an entire data center.

Example apparatuses provided herein may include an adjustable restrictor 122 (e.g., to provide air restriction), to adjust the intake of shared resource 104 to augment cooling by the first system 102 (an air handling unit). The apparatus 100 may include an actuator for the restrictor 122, to adjust the passage of outside air into apparatus 100. The restrictor 122 may be capable of fully blocking usage of the shared resource 104 by the apparatus 100, by fully decreasing an opening of the restrictor 122. Restrictors 122 may be used to balance distribution of shared resource 104 among a plurality of apparatuses 100.

The shared resource 104 may be outside air. The controller 110 may compare an outside temperature with a return air temperature to determine whether the outside temperature is at least lower than the return air temperature. However, even if the outside temperature is lower than the return temperature, apparatus 100 does not need to use the maximum capacity possible of the second system 120 using shared resource 104. More specifically, there are costs associated with use of shared resource 104, which may include the use of fan power (which increases based on the cubic power of the fan speed). Thus, the controller 110 may compare and optimize the savings to be had, by comparing reliance solely on the first system 102 against the cost of bringing outside air in using fan power (or equivalent techniques and costs for shared resource 104 not based on outside air). The controller 110 also is associated with communication 112.

The communication 112 may be received by the controller 110, and may have originated from other devices broadcasting the communication 112. Thus, the controller 110 may passively receive broadcasted communication 112 based on the communication 112 being pushed out. In an alternate example, the controller 110 may actively request the communication 112, based on the communication 112 being pulled from other apparatuses 100. Thus, examples support both pull and push techniques for receiving and/or exchanging information, for collaborative decision making among different apparatuses 100. Such collaboration based on communication 112 is to extend capabilities of the apparatus 100 beyond those available in a single local unit acting according to its own rules without collaborating. The communication 112 may be exchanged using wired and/or wireless approaches. In an example, communication 112 may take the form of a communications protocol for building automation and control networks, and may conform with ASHRAE, ANSI, ISO, and other standard protocols. For example, the communication 112 may be based on BACnet protocol. Communication 112 may include information relating to a hardware unit (e.g., an air handler), such as unit identification, location, current cooling/heating load, supply temperature, supply temperature set point, return air temperature, and so on. Each apparatus 100 may provide such information about itself, and receive such information regarding other units. Thus, communication 112 may be sent by controller 110 as well as received.

In some situations, such as a high-density computing area that is associated with high levels of localized heat generation, the first system 102 and/or second system 120 of apparatus 100 may saturate a cooling capacity of the systems. Thus, in such conditions, a system operating at capacity may be said to be underprovisioned or insufficiently provisioned, because further temperature adjustments (applying cooling or heating resources) may not be easily achieved by a system operating at its capacity. The apparatus 100 may need additional shared resource 104 (e.g., outside air), but there may not be enough cool air to satisfy the cooling needs of the localized hot area, even though the restrictor 122 of second system 120 may be wide open while operating at capacity. The distribution of the shared resource 104 throughout a site can affect availability of cool air for a given localized area (e.g., a hot spot), as well as whether the overall total of available shared resource 104 is exhausted. Communication 112 enables the distribution of the shared resource 104 to best meet the needs of a given site. For example, an apparatus 100 may communicate its need for more shared resources, and others may reduce the opening of their restrictors 122 in response to such communication 112, so that additional shared resource 104 may be directed to the apparatus(es) 100 in need. Another situation may involve there not being enough cool air available for all the multiple apparatuses 100 (e.g., CRAG units) in a system/data center. Each apparatus 100 may have its restrictor 122 partially and/or wide open, but perhaps the shared resource 104 is taxed to the point that there is not enough available resource for all units. For example, the shared resource 104 may have delivery, humidity, and/or temperature issues, or there may be so many apparatuses 100 drawing from the shared resource 104, or other factors may cause the shared resource 104 to be unable to provide sufficient resources.

There may be a situation where a given apparatus 100 has enough temperature adjusting capacity between the first system 102 and the second system 120 to satisfy its needs. However, to satisfy an adjustment need, the apparatus 100 may rely on the second system 120 and further open the restrictor 122 (even though the apparatus 100 still had a margin of operation to achieve the needed temperature change using the first system 102 or other technique, without having to further deplete the shared resource 104). In such a situation, where use of the first system 102 and/or the second system 120 may be used to satisfy temperature needs, the apparatus 100 may check for communications 112 indicating a status of the shared resource 104, or whether other apparatuses 100 are in greater need of access to the shared resource 104. In such conditions, the apparatuses 100 that can tolerate using less of shared resource 104, may use their restrictor 122 to reduce distribution to themselves of the shared resource 104, allowing more shared resources 104 to be available to other air handling units that may have a greater need.

Examples provided herein may rely on communication 112 to exchange information with other apparatuses 100 to consider the temperature adjusting loads of each other. The apparatuses 100 may coordinate to direct the shared resource 104 to the high-load apparatus(es). In an example, an apparatus 100 may be capable of relying entirely upon its first system 102 for satisfying its temperature adjusting demands. However, if only considering itself, that apparatus may attempt to blindly reduce its own costs by using second system 120 for outside air cooling, thereby depleting a portion of the shared resource 104. But when considering an entire system of multiple apparatuses 100, the apparatuses 100 may exchange communications 112 with each other (or a manager unit) to determine that such an individually-motivated action is not an optimal solution if applied system-wide. In other words, an apparatus 100 may rely on an adjusting solution for itself that may be sub-optimal for itself from its own perspective, to generate an overall systemic benefit (including the benefit of being able to salvage an otherwise failed apparatus 100, e.g., whose first system 102 has failed and relies entirely on a surplus of the shared resource 104 being available to compensate). In an example, apparatus 100 may look for communications 112 indicating whether some of the apparatuses 100 (CRAC units) elsewhere are reaching 100% capacity or even failing. The present apparatus 100 may sacrifice its own use of the second system 120 (that uses the shared resource 104), to thereby enable shared resources 104 to be diverted to the other units elsewhere that are in greater need.

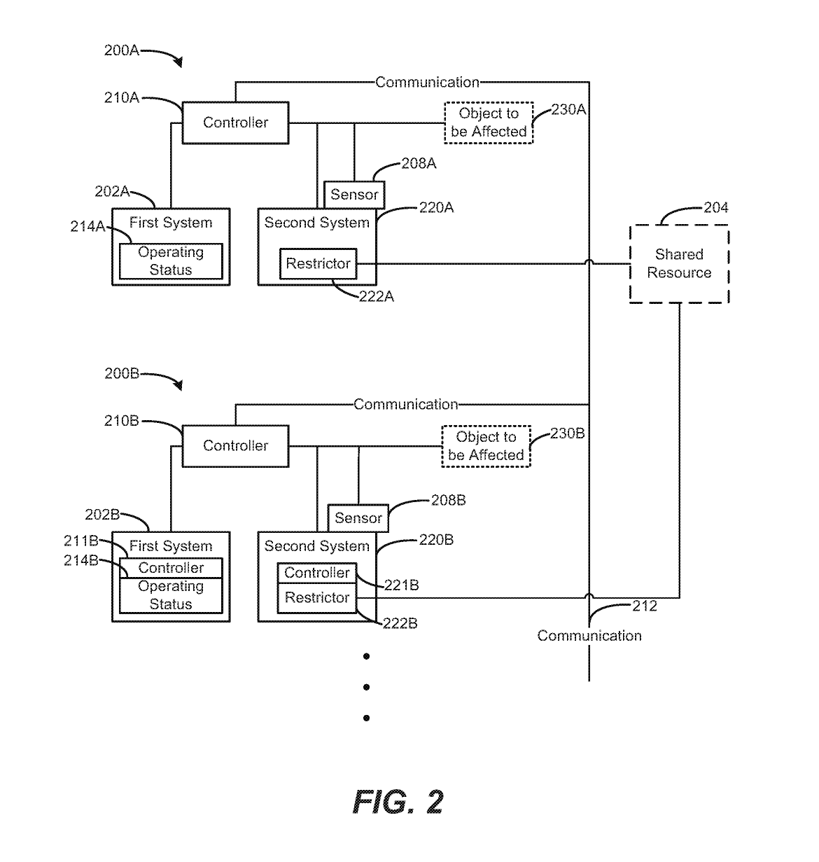

FIG. 2 is a block diagram of a plurality of units 200A, 200B in communication 212 with each other according to an example. A unit 200A, 200B includes a controller 210A, 210B coupled to a first system 202A, 202B, second system 220A, 220B, and sensor 208A, 208B, and is associated with object to be affected 230A, 230B. The first system 202A, 202B is associated with operating status 214A, 214B. A first system 202A, 202B may be associated with a controller, such as controller 211B shown in first system 202B. The second system 220A, 220B includes a restrictor 222A, 222B associated with a shared resource 204. The second systems 220A, 220B also may include a controller 221B, which may be an embedded controller or other type of controller. Two units/objects 200A, 200B are shown for convenience, although an arbitrary number of units may be included in a system.

The first systems 202A, 202B and second systems 220A, 220B may include their own controller, and/or may be controlled by controllers 210A, 210B. Unit 200A includes first system 202A and second system 220A shown without their own controller (e.g., first system 202A and second system 220A are controlled directly by controller 210A, and controller 210A may directly obtain sensor data or other operating status 214A from the first system 202A or second system 220A). Unit 200B is shown including a first system 202B having a controller 211B and operating status 214B, and a second system 220B having controller 221B. Controller 211B, 221B may be an embedded controller or other type of controller in the first system 202B (which may be, e.g., a CRAC unit or other implementation such as an air handler) and second system 220B for controlling a first resource and other sensors/restrictors/resources. In an example, the controller 211B (and/or 221B) may control a valve in the first system 202B for chilled water to change the water flow, and/or control a fan to adjust the air flow, or otherwise use a supply temperature and other performance commands. The controller 211B, 221B may monitor a supply air temperature, a supply temperature set point, or other information that may be included as part of operating status 214B of the first system 202B. Thus, a controller 210B can interact with the controller 211B/221B, including collecting data regarding operating status 214B, and providing commands to controller 211B/221B regarding the operation of the first system 202B and second system 220B.

The sensor 208A, 208B may be optional, and may be used to monitor a status of the restrictor 222A, 222B or other components, and communicate with controllers 210, 211, and/or 221. In an alternate example where sensor 208A, 208B is not used, the controller 210A, 210B (or other controller) may keep track of the most recent adjustment command sent to adjust the restrictor 222A, 222B, and refer to that setting to reflect the current status of the restrictor 222A, 222B. The controller 210A, 210B may compensate for variations in usage of the shared resource 204 in view of a given restrictor setting, based on variations such as the varying pressure drops caused by different lengths of ducts, or other factors.

Example controllers 210A, 210B, 211B, 221B may include the ability to monitor an object to be affected 230A, 230B. Objects may include equipment, people, rooms/spaces, or other objects that are affected by temperature adjustment, whether cooling, heating, or temperature maintenance. Thus, in addition to checking a temperature adjusting load of a unit 200A, 200B, controller 210A, 210B also may check for anomalous conditions at the object 230A, 230B to be treated (e.g., whether it is overheating). A unit 200A, 200B may be responsible for a certain array of objects, to maintain their temperature below their threshold, and ensure the objects are not overheating. Thus, by monitoring the object(s) to be affected 230A, 230B, the controller 210A, 210B can receive direct insight into the effects that a given set of cooling/heating inputs may provide to the target equipment etc.

Thus, by monitoring objects 230A, 230B, controller 210A, 210B has the ability to identify objects 230A, 230B that are not jeopardized (e.g., by overheating), and divert shared resources 204 away from the corresponding units 200A, 200B for those objects 230A, 230B. Similarly, the controller 210A, 210B may focus shared resources 204 toward those units 200A, 200B whose objects 230A, 230B are facing more severe temperature situations, thereby receiving a higher priority in terms of allocating the shared resource 204.

Accordingly, in addition to considering various loads of the unit 200A, 200B itself (and other units), a controller 210A, 210B may consider status of objects 230A, 230B whose temperature the air handling unit 200A, 200B is trying to maintain. Overheated objects 230A, 230B (e.g., as identified by the controller 210A, 210B) may result in the controller 210A, 210B placing a higher priority for the corresponding unit 200A, 200B to receive the shared resource 204. Thus, examples herein may consider a temperature adjusting load of a unit 200A, 200B, and even if the load is at a maximum capacity, the object(s) receiving the benefit of that unit 200A, 200B may still be determined by the controller 210A, 210B to represent an acceptable operation (e.g., not overheated). Thus, units 200A, 200B have the flexibility to maintain a temperature condition/status even when at max capacity load, because the controller 210A, 210B has the flexibility of knowing the situation at the object 230A, 230B itself and whether it is overheating. Accordingly, the units 200A, 200B may achieve finely tuned operational situations that are not achievable in other systems. If it turns out that the object 230A, 230B overheats, units 200A, 200B may observe this directly (e.g., without a need to infer the situation or incur a time lag), and may rapidly allocate the cooling resource 204 (and/or first system 202A, 202B, as needed) to provide maximum usage by the air handling unit 200A, 200B having overheating equipment.

In other words, even if a temperature adjusting load is maxed out at a unit 200A, 200B, then the controller 210A, 210B can consider a status of the object 230A, 230B. If the status of object 230A, 230B is acceptable, then the unit 200A, 200B can maintain the current status or perhaps open the restrictor 222A, 222B a first amount. Depending on the status of object 230A, 230B, the controller 210A, 210B can open the restrictor 222A, 222B varying amounts to use shared resource 204. If the object 230A, 230B is overheated, and the restrictor 222A, 222B is maxed out, the controller 210A, 210B even can generate a communication 212 indicating itself and its status to other units, so that they may decide whether to decrease their usage of shared resource 204, so that more resource 204 is available for diverting to the overheated object 230A, 230B of unit 200A, 200B.

Thus, a plurality of units 200A, 200B in communication 212 with each other may allocate resources based on, e.g., not having enough outside air to be used everywhere. Units 200A, 200B may coordinate to direct the shared resource 204 to where it can do the most good, e.g., using load balancing among units 200A, 200B to increase the capacity of the high-density areas.

Another situation involves there being enough cooling shared resource 204 for all units 200A, 200B, so that controllers 210A, 210B may distribute resources in an optimized pattern in view of availability and costs. For example, the shared resource 204 may represent a source of outside air entering through a primary duct and branching off to various units 200A, 200B. Depending on the locations of the units 200A, 200B relative to the inlet of the primary duct carrying outside air, those different units 200A, 200B will be associated with varying duct distances that the air must traverse before reaching a restrictor 222A, 222B. Thus, corresponding units 200A, 200B will receive varying amounts of air, even for the same given opening of the restrictor 222A, 222B between those units (e.g., based on different pressure drops along the primary duct according to different distances). Accordingly, some of the units 200A, 200B may set their restrictor 222A, 222B to a value that may end up with more than enough of the shared resource 204 at that unit, due to the increased pressure from proximity to the primary duct supplying cool air. Conversely, some units will end up with less than expected resources for a given restrictor setting, due to a longer distance and greater pressure drop at the restrictor. Such units 200A, 200B receiving extra shared cool air due to this distance/pressure effect may result in an over-cooled area. Furthermore, some areas happen to have a low density distribution of equipment (objects 230A, 230B), that does not need much temperature adjusting. Such factors may combine to result in a doubly over-cooled area. Accordingly, the controller 210A, 210B may detect this situation, and identify such an area as a resource to be harvested for the surplus of shared resource 204 (that might otherwise go to waste overcooling, and therefore be better diverted elsewhere). The controllers 210A, 210B also may compensate for these effects, e.g., by restricting the air distribution to those units (i.e., by recalibrating the settings for the restrictor 222A, 222B to better match the intended results as measured by the controller 210A, 210B at the objects 230A, 230B). The controller 210A, 210B may redirect these shared resources 204 to areas where it is more needed. Alternatively, the controller 210A, 210B may save costs by altogether avoiding a need for those resources overall, if not needed elsewhere, and reducing an overall load on the air movers supplying the shared resource 204. Regardless of scenario, the features described above may result overall in less outside air being needed, lowering a need for intake fan power, exhaust fan power, and associated costs.

Accordingly, in examples having a surplus of shared resources 204 to distribute, overall costs may be lowered by better distribution that is well suited to the particular needs and nuances of a given cooling setup. In examples where there is not enough shared resource 204 to distribute to the units, cool air resources may be distributed to high-load units. In an example, when some of the first systems 202A, 202B are down/disabled, the controllers 210A, 210B may coordinate to direct the shared resource 204 to the failed units corresponding to those down systems 202A, 202B, to enable enhanced cooling via the second systems 220A, 220B to compensate for down systems 202A, 202B.

Controller 210A, 210B may adjust units 200A, 200B based on a supply air temperature (e.g., temperature of outgoing air conditioned by the unit) and a supply air temperature set point (e.g., targeted temperature of air output by the unit to be used for affecting an object 230A, 230B), in addition to a load/capacity of the units and a status of the object to be affected 230A, 230B. Units may take advantage of shared resource 204 when it is appropriate, resulting in cost savings by taking advantage of the cooling capacity provided by the shared resource 204. However, if the controller 210A, 210B determines that the load of a unit 200A, 200B is above zero, it may direct the restrictor 222A, 222B to use just enough of the shared resource 204, e.g., without using too much so that the load of the unit drops to zero and the supply air temperature goes below the set point. The controllers 210A, 210B may limit usage of the shared resource 204 by knowing whether other units are in more need of the shared resource 204, for those running at their capacity or in a failed status.

The controller 210A, 210B of a given unit 200A, 200B may exchange/share information with some or all other controllers (including from those units that are remote from the given unit). The information may be carried by communications 212 sent using different techniques. Some or all units may send and receive communications 212, and units may send and receive as groups (e.g., one controller 210A, 210B sending/receiving for a plurality of other units 200A, 200B). Communication may be periodic (e.g., sending and/or receiving every 20 seconds or other period). The communications 212 may include operating status 214A, 214B information such as unit identification, return air temperature, supply air temperature set point, load, sensor readings, restrictor settings, status of object to be affected, etc., which may be encompassed in the operating status 214A, 214B.

In an example, it is possible to infer that a unit 200A, 200B or component thereof (e.g., first/second system) is down or otherwise malfunctioning, based on listening for communications and failing to receive a message from a certain unit (as identified by a unit identifier associated with a communication), e.g., for a period of time. The assumption that the unit is down may enable other controllers 210A, 210B to assume that the area covered by the certain unit may be overheated or otherwise experiencing problems in maintaining the desired status of the object to be affected 230A, 230B. In this case, other units may reduce their usage of the shared resource 204 to enable additional shared resource 204 to be directed to the failed unit whose failure was inferred based on a detected failure to communicate.

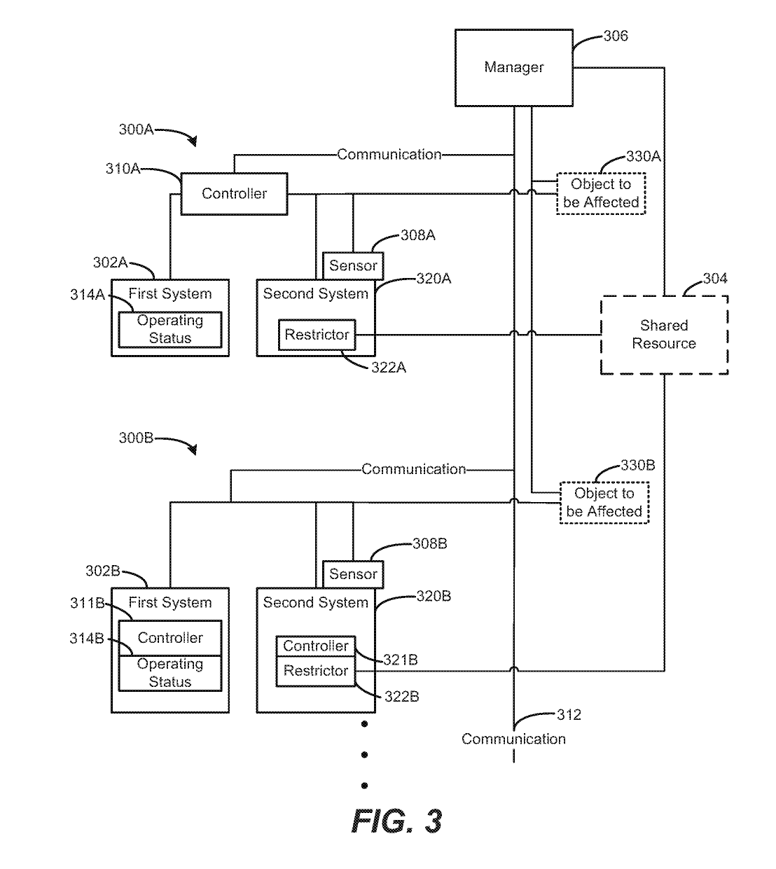

FIG. 3 is a block diagram of a plurality of units 300A, 300B in communication 312 with a manager 306 (and/or each other) according to an example. A unit 300A includes a controller 310A coupled to a first system 302A, second system 320A, and sensor 308A, and is associated with object to be affected 330A. The first system 302A is associated with operating status 314A. The second system 320A includes a restrictor 322A associated with a shared resource 304. An example unit 300B is shown without a dedicated controller 310A. Unit 300B may be provided with controller functionality from manager 306 (and/or embedded controllers in first/second systems 302B, 320B). Unit 300B includes first system 302B, second system 320B, and sensor 308B, and is associated with object to be affected 330B. The first system 302B is associated with controller 311B and operating status 314B. The second system 320B includes a controller 321B and a restrictor 322B associated with a shared resource 304.

The manager 306 (which itself may be a controller 310A, another unit 300A, 300B, or other component) can enable centralized collaboration between units 300A, 300B, and also may work in conjunction with distributed communication among the units themselves. The manager 306 may be provided as a designated unit/apparatus (such as unit 300A, 300B, etc.) to provide managing services to other units. The manager 306 may be a processor running computer software to monitor a status/mode of the different units 300A, 300B. For example, the manager 306 may monitor an outside temperature and other data corresponding to the various other components described above. The manager may determine, based on such data, how much shared resource 304 (e.g., outside air) to use, how to distribute it, how to maintain the restrictors 322A, 322B, and so on. Thus, the manager 306 may remotely process information that a controller 310A, 311B of a unit 300A, 300B may process. The manager 306 may manage large numbers of units 300A, 300B, and may be combined with other managers and/or controllers 310A, 311B to handle the distribution of the shared resource 304. The units 300A, 300B may communicate with each other, in addition to communicating with the manager 306. In an alternate example, the controller 310A of unit 300A may be omitted and its functions handled by the manager 306. Thus, the units 300A, 300B may be controlled remotely by the centralized manager 306 acting as a controller for a given unit.

Units 300A, 300B may send communications 312 including information statuses to the manager 306, and the manager 306 may monitor and/or collect various types of communications 312. Units 300A, 300B may retrieve information from the manager 306. For example, the manager 306 may push and/or pull information to/from the units 300A, 300B, and vice versa.

The manager 306 may be in communication with other components, such as the shared resource 304, the objects to be affected 330A, 330B, and controllers 310A, 311B, 321B (which may provide communication between the manager 306 and various other components in the units 300A, 300B). Thus, the communication 312 may include aspects relating to a status of the shared resource 304, as well as status information regarding objects to be affected 330A, 330B (e.g., whether the object is overheated). The manager 306 may store/use such information, and share it with the units 300A, 300B.

The manager 306 may include, or work in conjunction with, a building management system (BMS) or other information system to collect sensor information readings, run services, and/or obtain other information about the equipment, including sending commands to the equipment to change the equipment status. For example, the manager 306 may participate in changing operational characteristics for functioning properly across seasonal temperature changes. The manager 306 may include data aggregation to store such data and act upon it regarding control of the units 300A, 300B and other components.

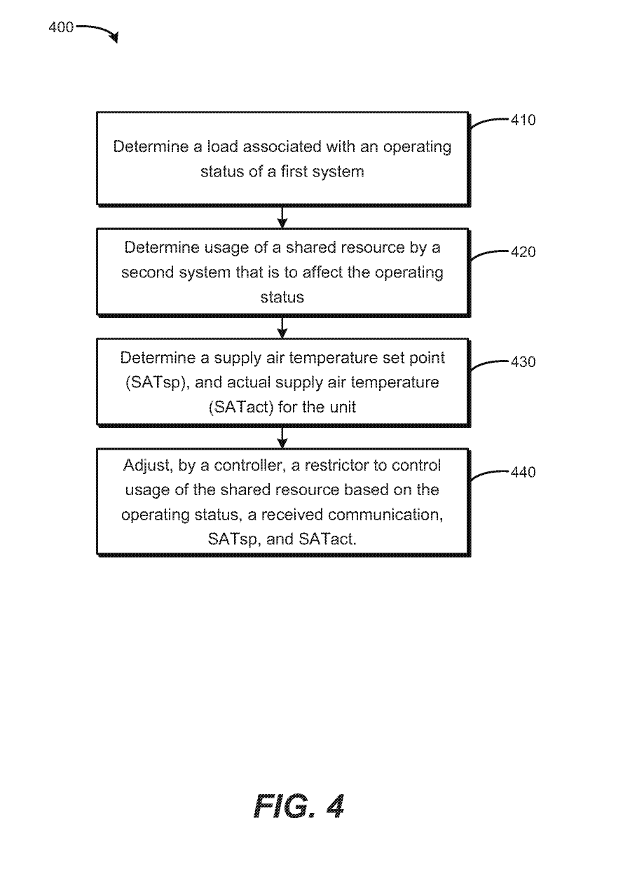

Referring to FIGS. 4-6, flow diagrams are illustrated in accordance with various examples of the present disclosure. The flow diagrams represent processes that may be utilized in conjunction with various systems and devices as discussed with reference to the preceding figures. While illustrated in a particular order, the disclosure is not intended to be so limited. Rather, it is expressly contemplated that various processes may occur in different orders and/or simultaneously with other processes than those illustrated.

FIG. 4 is a flow chart 400 based on adjusting a restrictor to control usage of a resource according to an example. In block 410, a load is determined of a first system as indicated in an operating status. For example, a controller may determine that a unit has an operating status indicating zero load, partial load, operating at capacity, disabled, and so on. In block 420, usage is determined of a shared resource by a second system that is to affect the operating status. For example, the controller may determine that a restrictor of the second system is partially allowing usage of a shared cooling/heating resource for cooling by the second system. In block 430, a supply air temperature set point (SATsp), and actual supply air temperature (SATact) for the unit are determined. For example, the controller may determine that the actual supply air temperature is above the supply temperature set point by an amount greater than an error value/dead band, which indicates that further cooling may be appropriate. In block 440, a controller is to adjust a restrictor to control usage of the resource based on the operating status, a received communication, SATsp, and SATact. For example, the controller may receive a communication that indicates that the shared cooling resource is not being used by that unit, and the operating status indicates that the cooling load is greater than zero, and that the SATsp and SATact indicate that further cooling is appropriate. Based on these values, the controller may decide to open the restrictor further and make further use of the shared cooling resource, without jeopardizing the health of other air handling units and/or their objects to be affected (cooled/heated).

In an example further illustrating the blocks of FIG. 4, a controller may execute the following control logic over time (e.g., at predefined time periods, at intervals determined by interrupts, etc.). First, a controller is to collect the load (in percentage), the supply air temperature set point (SATsp), and the actual supply air temperature (SATact) of each air handling unit. If no air handling unit has its load level equal or above a predefined major threshold (meaning the CRAG unit would be reaching its maximum capacity), the data center is deemed to be operating in a first (e.g., “normal”) operating mode. Otherwise, the data center is deemed to be operating in a second (e.g., “emergency”) mode.

In the first operating mode, if the load of an air handling unit is non-zero, its outside air restriction device (i.e., restrictor) may open the outside air pass way by a predefined amount. If the load of an air handling unit is zero and (SATsp−DBlower)<=SATact<=(SATsp+DBupper), then no change is made to the air restriction device (where DBlower is a lower dead band, and DBupper is an upper dead band, which may be equal and shown simply as DB). If the load of an air handling unit is zero and SATact<(SATsp−DBlower), then the outside air restriction device of the air handling unit is further closed up by a predefined amount.

In the second operating mode, the outside air restriction devices of air handling units reaching the load threshold further open up by a predefined amount. If the load of an air handling unit is below the predefined low load threshold, the outside air restriction device of this air handling unit is further closed up by a predefined amount. If the load of an air handling unit is between the low load threshold and the major high threshold, no change is made to its outside air restriction device. Alternate examples may take into consideration a status of an object to be cooled/heated byan air handling unit.

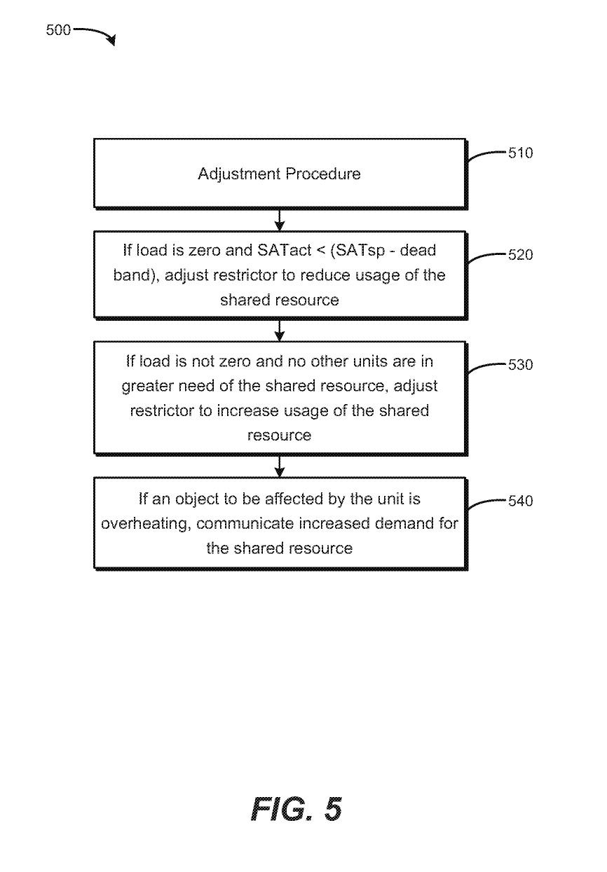

FIG. 5 is a flow chart 500 based on an adjustment procedure according to an example. The procedure begins in block 510. In block 520, if the load is zero and SATact<(SATsp−dead band), a restrictor is adjusted to reduce usage of the resource. For example, if the actual supply air temperature is below the supply air temperature set point, there is room to conserve the shared resource by reducing the restrictor. In block 530, if the load is not zero and no other units are in greater need of the shared resource, the restrictor is adjusted to increase usage of the shared resource. For example, the controller has determined that communications do not indicate another system at a higher priority of need, and a first system is maxed out and cannot generate additional cooling, so the second cooling system is increased by adjustment of the restrictor. In block 540, if an object to be affected by the unit is overheating, increased demand for the resource is communicated. For example, the first and second cooling systems may be maxed out, so the controller may broadcast a need for other air handling units to decrease usage of the shared resource, thereby enabling the present second cooling system to receive an additional portion of the shared cooling resource.

Throughout the present application, reference may be made to cooling units and cooling systems, among types of air handling units. However, the present application is applicable to heating systems as well (e.g., by reversing the greater than or less than symbols in various equations to accommodate the switch from cooling examples to heating examples). Thus, the present methods and drawings are merely exemplary, and may be used in other examples including heating, cooling, and/or temperature maintenance. The present application is not intended to be limited to cooling, and such examples are provided for simplicity of understanding and illustration.

The dead band (including a lower dead band and upper dead band, which may include different values) may be chosen to have values that ease the fluctuations of components such as switches, to conserve wear and tear on the various components. For example, the dead band may be chosen to avoid constantly cycling on and off various equipment. In an example, the dead band may be chosen to be two degrees, to maintain a temperature in a range considered acceptable, while avoiding extra wear on components.

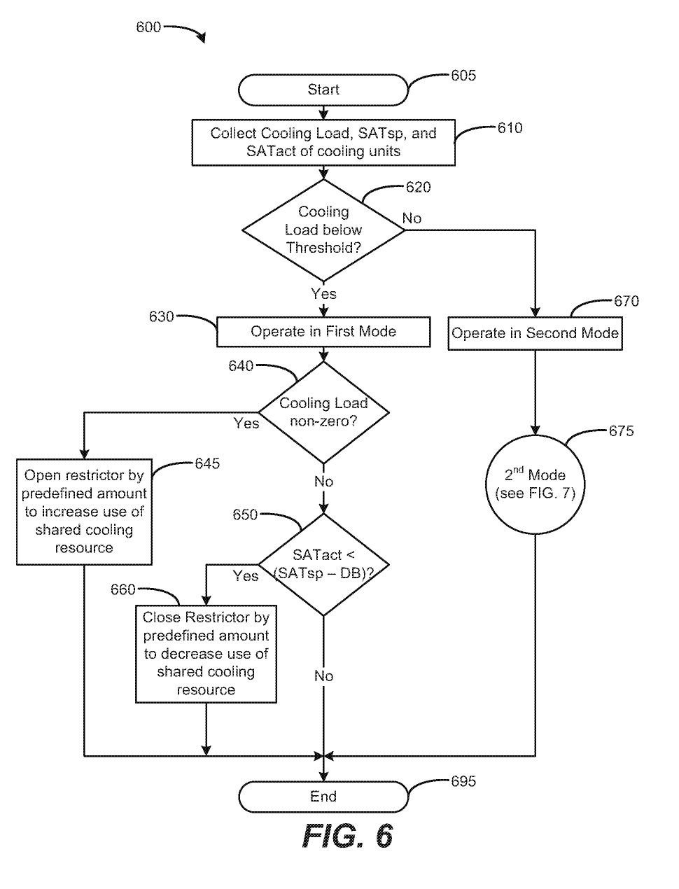

FIG. 6 is a flow chart 600 based on first and second modes of operation according to an example. Flow begins at block 605. In block 610, cooling load, SATsp, and SATact of air handling units are collected. In block 620, it is determined whether the cooling load is below a threshold. For example, a controller and/or manager may determine whether all or a designated selection of air handling units are operating within their cooling capacities. In an alternate example, a controller and/or manager may determine whether one or more air handling units is approaching or at its own cooling capacity (i.e., different air handling units may have different thresholds, which itself and/or a manager may keep track of per unit). In an alternate example, block 620 may enable the determination whether any air handling unit is not below its threshold, and enable each air handling unit to operate according to a first mode or second mode. If the determination at block 620 is yes, flow proceeds to block 630. In block 630, the system is to operate in a first mode. For example, the system may operate in a normal mode. In block 640, it is determined whether the cooling load is non-zero for a unit. For example, an object to be affected may be generating heat, such that the corresponding air handling unit bears a load. If yes, flow proceeds to block 645. In block 645, a restrictor is opened by a predefined amount to increase use of a shared cooling resource, and flow ends. If in block 640 the cooling load is not non-zero, flow proceeds to block 650. In block 650, it is determined whether SATact<(SATsp−dead band). If yes, flow proceeds to block 660. In block 660, the restrictor is closed by a predefined amount to decrease use of the shared cooling resource, and flow ends. If the result of the evaluation at block 650 is no, flow ends at block 695.

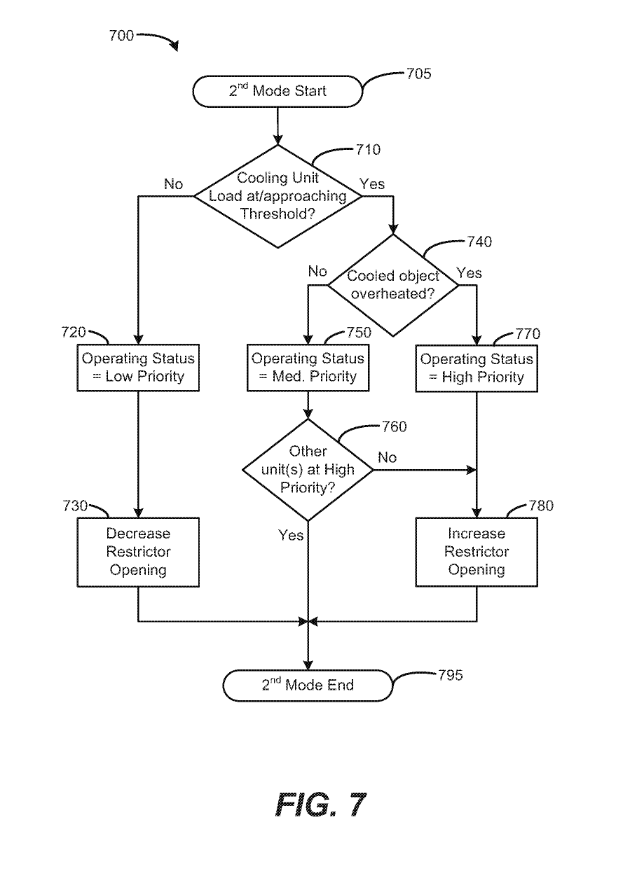

If, at block 620, the cooling load (e.g., of any unit) is not below a threshold, flow proceeds to block 670. In block 670, the system is to operate in a second mode, e.g., emergency mode. In an example, for some units the cooling load may be at the threshold, and the controller may look at the status of objects to be affected, for those air handling units whose load is at or above a threshold. For the air handling units associated with overheating equipment, the controller is to open up its restrictor a larger amount if other units are not at a higher priority. For the air handling units that have a load at or above its threshold, but without overheating equipment, the controller may keep its current restrictor setting if other units are at a higher priority for the shared resource, and may open up its restrictor if no other units are at a higher priority. For cooling equipment with a load below its threshold, the controller is to close the restrictors some predetermined amount. A detailed example of second mode operation is provided in FIG. 7. Flow ends at block 695.

FIG. 7 is a flow chart 700 based on a second mode of operation according to an example. Flow begins at block 705, e.g., corresponding to block 675 of FIG. 6. In block 710, it is determined (e.g., by a controller) whether a load of an air handling unit is at or approaching a threshold (e.g., reaching its cooling capacity). If not, flow proceeds to block 720. In block 720, the operating status for that air handling unit is assigned a low priority (which may be communicated with other controllers, air handling units, and/or managers, as with the medium and high or other priorities). In block 730, the restrictor opening for that air handling unit is decreased (e.g., decreasing usage of the shared resource), and flow ends at block 795. If, at block 710, air handling unit is at or approaching its threshold, flow proceeds to block 740. In block 740, it is determined whether a cooled object associated with that air handling unit is overheated (or otherwise approaching a type of threshold status for that object). If not, flow proceeds to block 750. In block 750, the operating status for that air handling unit is assigned a medium priority. In block 760, it is determined whether another air handling unit(s) is/are at a high priority. If yes, flow ends at block 795. If not, flow proceeds to block 780, where the restrictor opening for the present air handling unit is increased, and flow ends at block 795. If, at block 740, a cooled object corresponding to the present air handling unit is overheated, flow proceeds to block 770. In block 770, the operating status for that air handling unit is assigned a high priority. In block 780, the restrictor opening for that air handling unit is increased (e.g., if not already at maximum opening). Flow for the second mode ends at block 795.

Examples provided herein may be implemented in hardware, software, or a combination of both. Example systems can include a processor and memory resources for executing instructions stored in a tangible non-transitory medium (e.g., volatile memory, non-volatile memory, and/or computer readable media). Non-transitory computer-readable medium can be tangible and have computer-readable instructions stored thereon that are executable by a processor to implement examples according to the present disclosure.

An example system (e.g., a computing device) can include and/or receive a tangible non-transitory computer-readable medium storing a set of computer-readable instructions (e.g., software). As used herein, the processor can include one or a plurality of processors such as in a parallel processing system. The memory can include memory addressable by the processor for execution of computer readable instructions. The computer readable medium can include volatile and/or non-volatile memory such as a random access memory (“RAM”), magnetic memory such as a hard disk, floppy disk, and/or tape memory, a solid state drive (“SSD”), flash memory, phase change memory, and so on.

Examples provided herein may improve the distribution of cooling resources from outside air economization among the multiple air handling units. In addition to reduced total outside air flow demand which leads to energy savings from the air movers, the outside air distribution can also be used to mitigate such adverse conditions as air handling units approaching their cooling capacity, and assist in emergence response such as loss of other cooling means, such as chilled water or refrigeration based cooling

What is claimed is:

1. An apparatus comprising:
a first system associated with an operating status;
a second system to affect the operating status based on usage of a shared resource;
a restrictor to control usage of the shared resource; and
a controller to adjust the restrictor to control usage of the shared resource based on the operating status and a received communication indicating a resource status.

2. The apparatus of claim 1, wherein the controller is to determine that the communication indicates increased demand for the shared resource elsewhere, and adjust the restrictor to reduce usage of the shared resource.

3. The apparatus of claim 1, wherein the controller is to identify overheating of an object to be cooled, and transmit a communication indicating increased demand for the shared resource.

4. The apparatus of claim 1, wherein the controller is to determine that the operating status indicates that the first system is operating at capacity, and transmit a communication indicating increased demand for the shared resource.

5. The apparatus of claim 1, wherein the controller is to determine that the operating status indicates that the first system is below a threshold and the communication indicates that other units are in greater need of the shared resource, and the controller is to adjust the restrictor to reduce usage of the shared resource in response to the determination.

6. The apparatus of claim 1, wherein the controller is to broadcast the operating status based on a pushed communication.

7. The apparatus of claim 1, wherein the controller is to pull communications based on a request to receive the communication.

8. The apparatus of claim 1, wherein the controller is adjust the restrictor based on the communication indicating a status of an object to be affected by the first and second systems.

9. The apparatus of claim 1, wherein the controller is to receive the communication from a manager that is to monitor usage, by a plurality of units, of the shared resource, based on monitoring operating statuses from the plurality of units.

10. A system comprising:
a manager to determine usage of a shared resource and communicate with a unit making use of the shared resource based on an operating status communication;
a unit, including:
a first system associated with an operating status;
a second system to affect the operating status based on usage of the shared resource;
a restrictor to control usage of the shared resource; and
a controller to communicate with the manager, wherein the controller is to adjust the restrictor to control usage of the shared resource based on the operating status and communication with the manager.

11. The system of claim 10, wherein the manager is to identify overheating of an object to be affected by the unit operating at capacity, assign a high priority operating status to the unit, and broadcast a communication to other units indicating the high priority operating status of the affected unit, such that other units may reduce usage of the shared resource.

12. A method, comprising:
determining a load associated with an operating status of a first system;
determining usage of a shared resource by a second system that is to affect the operating status;
determining a supply air temperature set point (SATsp), and actual supply air temperature (SATact) for the unit; and
adjusting, by a controller, a restrictor to control usage of the shared resource based on the operating status, a received communication, SATsp, and SATact.

13. The method of claim 12, further comprising:
determining that the load of the first system is zero;
determining that SATact<(SATsp−dead band); and
indicating, via the communication, that that the controller is to adjust the restrictor to reduce usage of the shared resource.

14. The method of claim 12, further comprising:
determining that the load is not zero and no other units are in greater need of the shared resource; and
indicating, via the communication, that that the controller is to adjust the restrictor to increase usage of the shared resource.

15. The method of claim 12, further comprising identifying overheating by an object to be affected by the unit, and communicating increased demand for the shared resource.
